(19) United States
(12) Patent Application Publication
(10) Pub. No.: US 2013/0313540 A1
(43) Pub. Date: Nov. 28, 2013

(54) METHOD FOR PRODUCING AN OPTOELECTRONIC COMPONENT AND OPTOELECTRONIC COMPONENT

(71) Applicant: Christian Kristukat, Buenos Aires (AR)

(72) Inventor: Christian Kristukat, Buenos Aires (AR)

(73) Assignee: OSRAM OPTO SEMICONDUCTORS GMBH, Regensburg (DE)

(21) Appl. No.: 13/983,064

(22) PCT Filed: Dec. 12, 2011
(86) PCT No.: PCT/EP2011/072404

§ 371 Date: Aug. 1, 2013

(30) Foreign Application Priority Data
Feb. 4, 2011 (DE) 10 2011 003 641.5

(51) Int. Cl. H01L 51/52; H01L 33/20

(52) U.S. Cl. CPC H01L 51/52; H01L 33/20
USPC 257/40; 438/46

(57) ABSTRACT

A method for producing an optoelectronic component includes: providing a substrate, applying a solution to a main side of the substrate, applying a standing ultrasonic field to the substrate and to the solution, curing and drying the solution to form a layer having a wavy top side facing away from the substrate, and applying a layer stack on the top side of the wavy layer, said layer stack being designed to generate light during the operation of the finished component.

### RELATED APPLICATIONS

The present application is a national stage entry according to 35 U.S.C. §371 of PCT application No. PCT/EP2011/072404 filed on Dec. 12, 2011, which claims priority from German application No. 10 2011 003 641.5 filed on Feb. 4, 2011.

### TECHNICAL FIELD

Various embodiments provide a method for producing an optoelectronic component. Furthermore, various embodiments provide an optoelectronic component.

### SUMMARY

Various embodiments provide a method by which an optoelectronic component from which radiation can be coupled out efficiently can be produced.

In accordance with at least one embodiment of the method, said method includes the step of providing a substrate. The substrate is preferably designed to mechanically carry the optoelectronic component produced by the method. By way of example, the substrate includes or consists of a glass, of quartz, of a plastic, of a plastic film or of a semiconductor material. Preferably, the substrate is at least partly transmissive, in particular transparent, to radiation in the visible spectral range. The substrate has a main side that is preferably fashioned in a planar manner. A mean roughness Rₐ of the main side is, in particular, at most 20 nm or at most 5 nm.

In accordance with at least one embodiment of the method, said method includes the step of applying a solution on the main side of the substrate. The solution is preferably a polymer suspension. Likewise, it is alternatively or additionally possible for one or more types of particles to be dispersed in the solution. Such particles have, for example, an average diameter of at most 10 μm or, preferably, of at most 5 μm or of at most 1 μm. The particles consist of or include, in particular, one or more of the following materials: a metal, silver, gold, a metal oxide, a titanium oxide such as titanium dioxide, carbon. The particles can be shaped spherically or approximately spherically. It is likewise possible for the particles to be shaped in a cylinder-like or wire-like fashion and to have an average longitudinal extent greater than the average transverse extent for example by at least a factor of 3 or a factor of 5 or a factor of 10. In particular, the particles can be carbon nanotubes.

In accordance with at least one embodiment of the method, a standing ultrasonic field is applied to the substrate and/or to the solution. By means of such an ultrasonic field, density modulations can be produced in the solution. In particular, it is possible for polymers or particles in the solution to accumulate to an increased extent at oscillation nodes of the standing ultrasonic field.

In accordance with at least one embodiment of the method, said method includes the step of curing and/or drying the solution. A layer is formed during curing and/or drying. The layer has a wavy top side facing away from the substrate. The wavy layer is preferably formed directly on the main side of the substrate. In other words, a thickness of the layer fluctuates. The local thickness of the wavy layer corresponds, for example, to a density of the polymers or of the particles of the solution which is brought about by the standing ultrasonic field during the curing and/or drying of the solution. The curing and/or drying take(s) place, for example, by evaporation of a solvent of the solution.

In accordance with at least one embodiment of the method, the finished optoelectronic component is designed to generate light. For this purpose, a layer stack designed to generate light is applied, in particular, directly to the top side of the wavy layer.

In at least one embodiment of the method, said method serves for producing an optoelectronic component and includes at least the following steps:
providing a substrate,
applying a solution to a main side of the substrate,
applying a standing ultrasonic field to the substrate and/or to the solution,
curing and/or drying the solution to form a layer having a wavy top side facing away from the substrate, and
applying a layer stack on the top side of the wavy layer, said layer stack being designed to generate light during the operation of the finished component.

The individual steps of the method are preferably carried out in part or completely in the order indicated.

The layer can be structured by the standing ultrasonic field during production. Such a structuring makes it possible to increase a light coupling-out efficiency of radiation from the component. By means of ultrasound, a structuring of the wavy layer can be produced relatively simply and cost-effectively, compared with methods such as photolithographic patterning or embossing and stamping methods.

In accordance with at least one embodiment of the method, the layer stack designed to generate radiation replicates a shape of the wavy layer. In other words, the wavy structure of the wavy layer continues in particular through the entire layer stack. A side of the layer stack which faces away from the substrate, for example, with a tolerance of at most 20% or of at most 10% or of at most 5% of an average wave height of waves of the wavy layer, is shaped like the top side of the wavy layer which faces away from the substrate. In this case, the average wave height is an average distance, measured in particular in a direction perpendicular to the main side of the substrate, from wave valleys to wave peaks of the wavy layer. In other words, the layer stack can have a stack thickness that is constant across the wavy layer.

In accordance with at least one embodiment of the method, the wavy layer is a continuous layer. By way of example, the wavy layer covers an entire partial region of the main side of the substrate above which the layer stack is applied. The wavy layer is therefore preferably a continuous layer which completely covers the partial region of the main side having the layer stack of the substrate, without leaving holes or islands not covered by the wavy layer.

In accordance with at least one embodiment of the method, the wavy layer is not a continuous layer. In other words, the wavy layer is formed by individual strips and/or by individual islands on the main side, wherein the strips and/or islands are not connected to one another by a material of the wavy layer. It is likewise possible for the wavy layer to constitute a continuous material assemblage, but for the main side of the substrate not to be covered by the wavy layer in partial regions enclosed by the wavy layer. By way of example, the wavy layer is a net-like structure, preferably having a multiplicity of continuous intersecting webs.

In accordance with at least one embodiment of the method, an average periodicity of waves of the layer corresponds to an average half-wavelength of ultrasonic waves of the standing ultrasonic field in the solution. The average periodicity is, in particular, an average distance between adjacent wave valleys in a lateral direction, for example parallel to the main side of the substrate. A periodicity of the wave-like structures of the layer is therefore adjustable through a choice of the wavelength of the ultrasound. By way of example, a local thickness of the wavy layer is all the smaller, the higher an average intensity of the standing ultrasonic field was at the relevant location during the curing and/or drying of the solution.

In accordance with at least one embodiment of the method, the wavy layer and/or the substrate are/is at least partly transmissive to the light generated in the layer stack. This enables light to be coupled out through the wavy layer and through the substrate. A transmittance for the generated light is, for example, at least 80% or at least 90%.

In accordance with at least one embodiment of the method, the wavy layer is embodied in an electrically conductive fashion. This can enable the layer stack to be energized through the wavy layer.

In accordance with at least one embodiment of the method, the substrate includes an electrically conductive layer at the main side, which can serve as an electrode, in particular as an anode. By way of example, the electrically conductive layer is formed by a transparent conductive oxide, TCO for short. In particular, the substrate includes a layer composed of a zinc oxide, a tin oxide, an indium oxide or an indium tin oxide. The layer can be p-doped or n-doped.

In accordance with at least one embodiment of the method, the wavy layer is embodied as a hole injection layer for the layer stack. By way of example, the wavy layer includes a polyethylene dioxythiophene, PEDOT for short. The PEDOT is dissolved for example in water and/or an alcohol, in particular with concentrations of between 0.5 percent by weight and 3 percent by weight inclusive, and can be applied on the substrate by means of spin-coating.

In accordance with at least one embodiment of the method, the finished produced optoelectronic component is an organic light-emitting diode, OLED for short. The layer stack then includes at least one active layer which consists of at least one organic material or which includes at least one organic material. In particular, all layers of the layer stack are based on organic materials or consist thereof.

In accordance with at least one embodiment of the method, an electrode, in particular a cathode, is applied, for instance by means of vapor deposition, on that side of the layer stack which faces away from the substrate. Said electrode is preferably a metallic electrode, for example including or composed of one or more of the following materials: aluminum, barium, indium, silver, gold, magnesium, calcium, lithium. It is possible for the electrode to replicate the shape of the wavy layer and the layer stack. A structure of the wavy layer can therefore likewise be shaped in the electrode. The electrode forms a reflector or a mirror layer, for example.

In accordance with at least one embodiment of the method, the standing ultrasonic field is generated by at least two or exactly two or by at least four or exactly four ultrasound sources. Preferably, the ultrasound sources are aligned with one another orthogonally in pairs. In other words, main emission directions of the ultrasound sources can be oriented respectively perpendicularly to one another. The main emission directions of the ultrasound sources lie, in particular, in each case in a plane with the substrate and/or the solution for the wavy layer.

In accordance with at least one embodiment of the method, the ultrasound sources generate approximately plane waves in each case. As a result, a pattern or grid of the waves that is regular or approximately regular across the entire top side of the wavy layer can be produced. Plane wave can mean that a radius of curvature of wavefronts of the waves generated by one of the ultrasound sources is at least double or at least triple an average longitudinal extent of the wavy layer.

Furthermore, an optoelectronic component is specified. The component can be produced by means of a method as described in conjunction with one or more of the embodiments mentioned above. Features of the optoelectronic component are therefore also disclosed for the method described here, and vice versa.

In at least one embodiment, the optoelectronic component includes a substrate and a wavy layer on a main side of the substrate. Furthermore, the component includes a layer stack, which is provided for generating light during the operation of the component and which is applied on a top side of the wavy layer which faces away from the substrate. A shape of the layer stack is a replication of the wavy layer. A side of the layer stack which faces away from the substrate, in particular with a tolerance of at most 20% of an average wave height of waves of the layer, is shaped like the top side of the wavy layer which faces away from the substrate.

In accordance with at least one embodiment of the component, the wavy layer, as seen in plan view, is shaped like a one-dimensional or like a two-dimensional grid. The thickness of the wavy layer varies for example sinusoidally or rectangularly along, in particular, two main extension directions of the wavy layer, parallel to the main side of the substrate.

In accordance with at least one embodiment of the component, an average periodicity of the wavy layer is between 25 μm and 500 μm inclusive, in particular between 50 μm and 300 μm inclusive, for example approximately 100 μm. The ultrasonic radiation coupled into the substrate and/or the solution during the production of the layer then has for example an average frequency of between 3 MHz and 30 MHz inclusive.

In accordance with at least one embodiment of the component, the top side of the wavy layer which faces away from the substrate can be described by a continuous and/or periodic function. In particular, the top side can be described by a sine function or by a rectangular function or by a trapezoidal function. The top side is shaped for example in a manner similar to an egg carton having rounded edges.

In accordance with at least one embodiment of the component, the following holds true for a thickness T of the wavy layer along directions x, y:

T(x,y)=T0+0.5H(f(x)+f(y))

In this case, T0 is an average thickness of the wavy layer. H is the average wave height of the waves of the layer. x and y are preferably mutually orthogonal spatial directions parallel to the substrate, in particular parallel to main directions of the ultrasonic waves during the production of the wavy layer. f(x) and f(y) are functions from the space of periodic functions.

In accordance with at least one embodiment of the component, the average wave height of the waves of the layer is between 50 nm and 10 μm inclusive. Preferably, the average wave height is between 50 nm and 200 nm inclusive if the wavy layer is a continuous layer. If the wavy layer is embodied in a net-like or island-like fashion, then the average wave height is preferably between 0.5 μm and 10 μm inclusive or between 2 μm and 8 μm inclusive.

In accordance with at least one embodiment of the component, the average thickness T0 of the wavy layer, specifically in the case of a continuous layer, is between 15 nm and 500 nm inclusive, in particular between 25 nm and 100 nm inclusive. In this case, an average thickness of the layer stack provided for generating light is preferably between 50 nm and 2 μm inclusive or, preferably, between 100 nm and 500 nm inclusive.

In accordance with at least one embodiment of the component, the wavy layer is situated between two adjacent layers of the layer stack. It is therefore possible for at least one layer of the layer stack to be applied directly to the substrate and for said at least one layer then to be followed by the wavy layer and, on the wavy layer, further layers of the layer stack.

In accordance with at least one embodiment of the component, a covering layer is applied on a side of the layer stack which faces away from the substrate. The covering layer can be formed from a radiation-transmissive and electrically conductive material. It is possible for a covering layer top side facing away from the substrate to be shaped in a planar fashion and not to replicate a structure of the wavy layer.

In accordance with at least one embodiment of the component, the average longitudinal extent of the wavy layer is between 2 cm and 100 cm inclusive, in particular between 5 cm and 50 cm inclusive.

### BRIEF DESCRIPTION OF THE DRAWINGS

A component described here and a method described here are explained in greater detail below on the basis of exemplary embodiments with reference to the drawing. In this case, identical reference signs indicate identical elements in the individual figures. In this case, however, relations to scale are not illustrated; rather, individual elements may be illustrated with an exaggerated size in order to afford a better understanding.

In the figures:

FIG. 1 shows a schematic perspective illustration of a production method described here for a wavy layer described here, and

FIGS. 2, 3 and 4A to 4C show schematic illustrations of exemplary embodiments of optoelectronic components described here.

### DETAILED DESCRIPTION

The following detailed description refers to the accompanying drawings that show, by way of illustration, specific details and embodiments in which this disclosure may be practiced.

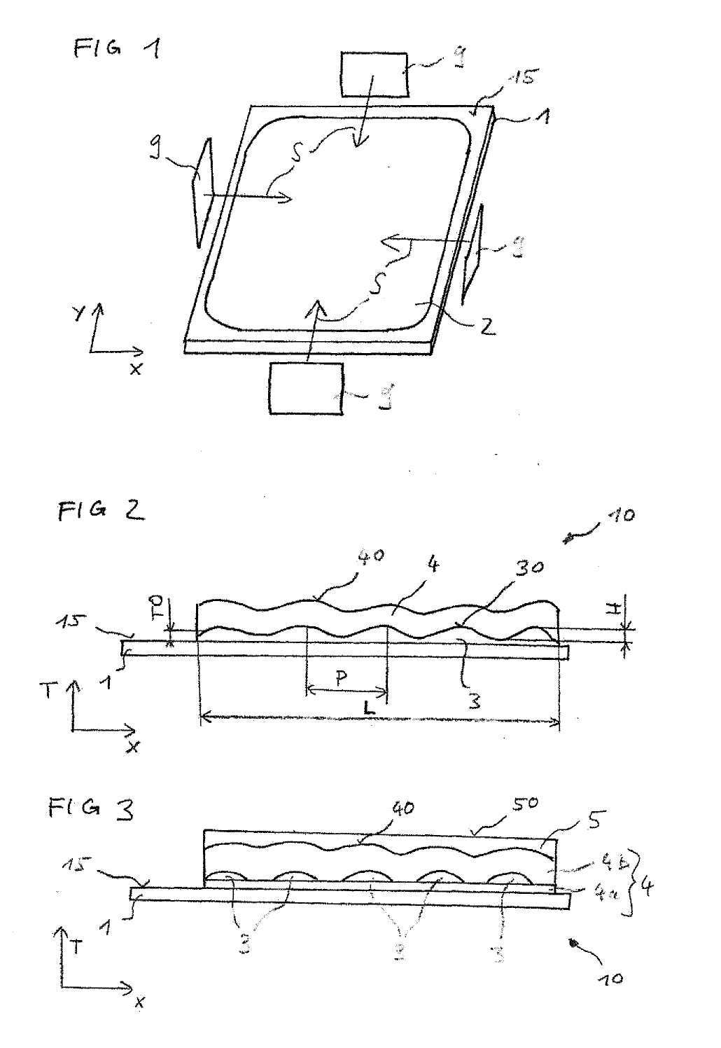

FIG. 1 illustrates a perspective illustration of the production of a wavy layer 3 for an optoelectronic component 10. A solution 2 composed of a solvent and a polymer is applied to a substrate 1, which is a glass substrate having an indium tin oxide coating on a main side 15, for example, on the main side 15.

The substrate 1 with the solution 2 is situated between four ultrasound sources 9 each having main emission directions S of the ultrasound, wherein the main emission directions S are oriented perpendicularly to one another in pairs. The main emission directions S lie approximately in a plane of main extension directions x, y of the substrate 1 and of the solution 2. In contrast to the illustration in FIG. 1, the ultrasound sources 9 are preferably in direct contact with the substrate 1 in order to efficiently couple the ultrasound into the substrate 1 and, via the latter, into the solution 2.

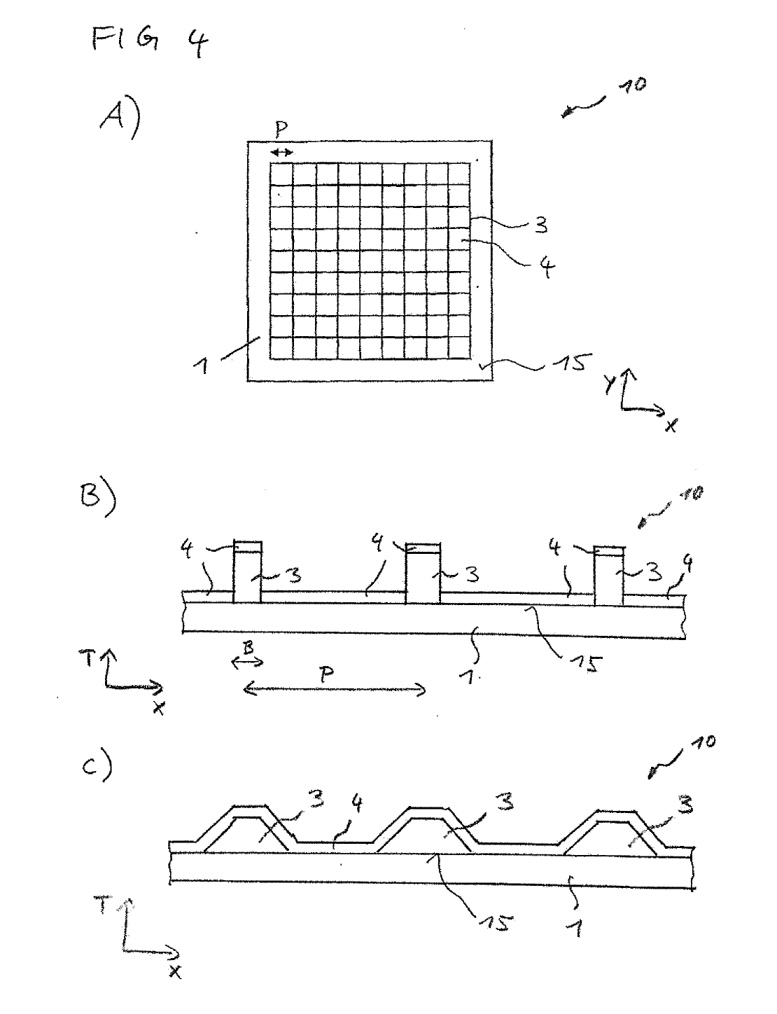

A standing ultrasonic field can be generated by the ultrasound sources 9. A density modulation of the polymers in the solution 2 can be produced by the standing ultrasonic field. Upon evaporation of the solvent of the solution 2, the polymers deposit on the main side 15 of the substrate 1 in accordance with the density modulation produced by means of the standing ultrasonic field. As a result, a wavy layer 3 having a wavy top side 30 facing away from the substrate 1 can be produced, also cf. FIG. 2. The wavy layer 3 remains on the substrate 1 and is not detached therefrom.

FIG. 2 shows a sectional illustration of the component 10, which is preferably an organic light-emitting diode. The continuous wavy layer 3 is applied on the substrate 1 directly on the main side 15. An average longitudinal extent L of the wavy layer 3 is approximately 20 cm, for example. A thickness T of the wavy layer 3 can be described by a sine function or by a sine squared function in the cross section along the x-direction. An average thickness T0 of the wavy layer 3 is approximately 200 nm, for example. An average wave height H between wave valleys and wave peaks in a direction perpendicular to the main side 15 of the substrate 1 is approximately 100 nm, for example.

The layer stack 4 is applied directly to a top side 30 of the wavy layer 3 which faces away from the substrate 1, said layer stack being designed for generating an electromagnetic radiation, in particular in the visible spectral range, during the operation of the component 10. The layer stack 4 replicates a shape of the top side 30 of the wavy layer 3 and has approximately a constant thickness. A side 40 of the layer stack 4 which faces away from the substrate 1 is therefore shaped approximately like the top side 30 of the wavy layer 3. The wavy layer 3 is preferably transparent to an electromagnetic radiation generated in the layer stack 4 during the operation of the component 10, and the substrate 1 is likewise preferably transparent thereto. Radiation is coupled out from the component 10 through the wavy layer 3 and through the substrate 1. A main side of the substrate 1 which faces away from the wavy layer 3 is preferably embodied as planar and smooth.

Particularly preferably, a reflective, metallic electrode is applied to the side 40 of the layer stack 4, said electrode not being depicted in the figures. Via said electrode and a further electrode, likewise not depicted, which the substrate 1 includes on the main side 15, and through the wavy layer 3, the layer stack 4 is energized for the purpose of generating light during the operation of the component 10.

As a result of the wavy structure of the layer 3 and/or of the electrode (not depicted) on the top side 40 and alternatively or additionally as a result of a difference in the refractive index of a material of the wavy layer 3 and of a material of the layer stack 4, a deflection of radiation can be effected, which increases an efficiency for coupling radiation generated in the layer stack 4 out of the component 10 and through the substrate 1. It is likewise possible that the wavy structure of the layer 3 reduces or prevents wave guiding of radiation in the layer stack 4 along the x-direction.

FIG. 3 shows a further exemplary embodiment of the component 10 in a sectional illustration. In this exemplary embodiment, the wavy layer 3 is not a continuous layer, but rather a layer having island-like regions. The wavy layer 3 is therefore not a closed layer which covers the main side 15 in a region in which the layer stack 4 is applied.

Optionally, the wavy layer 3, as also possible in all the other exemplary embodiments, is not applied directly to the main side 15 of the substrate 1, but rather to a first layer 4a of the layer stack 4. Further layers 4b of the layer stack 4 are applied to the top side of the wavy layer 3 which faces away from the substrate 1, and replicate a structure of the wavy layer 3. The one or the plurality of layers 4a of the layer stack 4 are shaped in a planar fashion within the scope of the production tolerances.

Furthermore, it is optionally possible, as also in all the exemplary embodiments, for a covering layer 5 having a planar covering layer top side 50 facing away from the substrate 1 to be applied on that side 40 of the layer stack 4 which faces away from the substrate 1 or on the electrode not depicted. A material of the covering layer 5 can be an encapsulation of the layer stack 4.

Preferably, all the layers of the layer stack 4 and/or of the wavy layer 3 are based on organic materials or consist of organic materials. A difference in the average optical refractive index of the material of the layer stack 4 and the materials of the wavy layer 3 is preferably at least 0.1, in particular at least 0.2 or at least 0.4.

The layers specified in the exemplary embodiments preferably follow one another directly in the order specified and are in each case in direct physical contact with one another. In a departure from this, it is likewise possible for the component 10 to include intermediate layers (not illustrated), which are not presented in the present context with the structure of the wavy layer 3 in order to simplify the illustration.

FIG. 4A shows a plan view and FIGS. 4B and 4C show sectional illustrations of a further exemplary embodiment of the component 10. The wavy layer 4 forms a continuous net-shaped structure on the substrate 1. The wavy layer 4 is formed for example with or from metal particles or carbon nanotubes. Via the wavy layer 4, in particular an efficient current distribution at the substrate 1 is then possible, for instance in combination with a thin, continuous layer (not depicted) composed of a transparent conductive oxide such as indium tin oxide. The average periodicity P of the wavy layer 4 is preferably between 250 μm and 5 mm inclusive or between 0.5 mm and 2 mm inclusive.

It can be seen in FIG. 4B that the periodic wavy layer 4 is shaped approximately like a rectangular function, for example, in cross section. In accordance with FIG. 4C, the wavy layer 4 is formed approximately like a trapezoidal function, for example. The layer stack 4 provided for generating radiation can break off at edges of the wavy layer 4, see FIG. 4B, or else be a continuous layer, see FIG. 4C. An average width B of webs of the wavy layer 4 is, in particular, between 2 μm and 60 μm inclusive or between 5 μm and 30 μm inclusive, such that the webs are preferably imperceptible to the naked eye. An average height of the webs is between 2 μm and 10 μm inclusive, for example.

While various embodiments have been particularly shown and described with reference to specific embodiments, it should be understood by those skilled in the art that various changes in form and detail may be made therein without departing from the spirit and scope of various embodiments as defined by the appended claims. The scope of various embodiments is thus indicated by the appended claims and all changes which came within the meaning and range of equivalency of the claims are therefore intended to be embraced.

### LIST OF REFERENCE SIGNS

10 Optoelectronic component
1 Substrate
15 Main side of the substrate
2 Solution
3 Wavy layer
30 Top side of the wavy layer
4 Layer stack for generating light
40 Side of the layer stack which faces away from the substrate
5 Covering layer
50 Covering layer top side
9 Ultrasound source
B Average width of webs of the wavy layer
H Average wave height of the wavy layer
L Average longitudinal extent of the wavy layer
P Average periodicity of the wavy layer
S Main direction of the ultrasound
T Height (x, y) of the wavy layer
T0 Average thickness of the wavy layer
x, y Directions

1. A method for producing an optoelectronic component comprising:
providing a substrate,
applying a solution to a main side of the substrate,
applying a standing ultrasonic field to the substrate and to the solution,
curing and drying the solution to form a layer having a wavy top side facing away from the substrate, and
applying a layer stack on the top side of the wavy layer, said layer stack being designed to generate light during the operation of the finished component.

2. The method as claimed in claim 1, wherein the layer stack replicates a shape of the wavy layer, wherein a side of the layer stack which faces away from the substrate, with a tolerance of at most 20% of an average wave height of waves of the layer, is shaped like the top side of the layer.

3. The method as claimed in claim 1,
wherein polymer chains are dissolved in the solution and wherein particles are dispersed in the solution.

4. The method as claimed in claim 1,
wherein the wavy layer is a continuous layer, wherein an average periodicity of waves of the layer corresponds to an average half-wavelength of ultrasonic waves of the standing ultrasonic field in the solution.

5. The method as claimed in claim 1,
wherein the wavy layer and the substrate are partly transmissive to the light generated in the layer stack.

6. The method as claimed in claim 1,
wherein the wavy layer is embodied in an electrically conductive fashion.

7. The method as claimed in claim 1,
wherein the standing ultrasonic field is generated by four ultrasound sources aligned orthogonally in pairs, said sources being situated in a plane with the substrate.

8. The method as claimed in claim 1,
wherein the finished produced component is an organic light-emitting diode, and wherein the layer stack comprises at least one organic material.

9. An optoelectronic component comprising:
a substrate,
a wavy layer on a main side of the substrate, and
a layer stack at a top side of the wavy layer which faces away from the substrate, said layer stack being provided for emitting light during the operation of the component,
wherein a shape of the layer stack is a replication of the wavy layer and a side of the layer stack which faces away from the substrate, with a tolerance of at most 20% of an average wave height of waves of the layer, is shaped like the top side of the wavy layer.

10. The optoelectronic component as claimed in claim 9,
wherein an average periodicity of the wavy layer is between 25 μm and 5 mm inclusive.

11. The optoelectronic component as claimed in claim 9,
wherein the top side of the wavy layer can be described by a continuous function.

12. The optoelectronic component as claimed in claim 9,
wherein the following holds true for a thickness T of the wavy layer along direction x, y:
T(x,y)=T0+0.5Hf(x)+f(y))
wherein f(x) and f(y) are in each case functions from the space of periodic functions,
T0 is an average thickness of the wavy layer,
H is the average wave height of the waves of the layer.

13. The optoelectronic component as claimed in claim 9,
wherein the average wave height of the waves of the layer is between 25 nm and 10 μm inclusive.

14. The optoelectronic component as claimed in claim 9,
which is produced by a method comprising:
providing a substrate,
applying a solution to a main side of the substrate,
applying a standing ultrasonic field to the substrate and to the solution,
curing and drying the solution to form a layer having a wavy top side facing away from the substrate, and
applying a layer stack on the top side of the wavy layer, said layer stack being designed to generate light during the operation of the finished component.

15. The method as claimed in claim 1,
wherein the finished produced component is an organic light-emitting diode, and
wherein the layer stack consists of one or more organic materials.
